(19) United States
(12) Patent Application Publication
(10) Pub. No.: US 2020/0061679 A1
(43) Pub. Date: Feb. 27, 2020

(54) ASSEMBLY AND METHOD FOR THE TREATMENT OF OBJECTS

(71) Applicant: Reylon Plasma GmbH, Regensburg (DE)

(72) Inventor: Stefan Nettesheim, Regensburg (DE)

(21) Appl. No.: 16/545,832

(22) Filed: Aug. 20, 2019

(30) Foreign Application Priority Data
Aug. 21, 2018 (DE) DE102018120269.5

(51) Int. Cl. B08B 7/00; H01J 37/32

(52) U.S. Cl. CPC B08B 7/0035; H01J 37/3244; H01J 2237/1825; H01J 2237/335; H01J 2237/186; H01J 37/32834

(57) ABSTRACT

An assembly and a method for treating at least one object are disclosed. An ionization chamber/plasma chamber is provided which is connected to a high-voltage source via a high-voltage line. A first valve group has a node and a second valve group has a node, a pump being provided between the first valve group and the second valve group. A treatment chamber is fluidic connectable to the first valve group and the second valve group, and the ionization chamber/plasma chamber is also fluidic connectable to the first valve group and the second valve group.

### CROSS-REFERENCE TO RELATED APPLICATIONS

The present non-provisional application is filed under 35 U.S.C. §§ 111(a) and 119 and claims the benefit of German Patent Application No. DE 10 2018 120 269.5, filed on Aug. 21, 2018, which application is incorporated herein by reference in its entirety.

### FIELD OF THE INVENTION

The present invention relates to an assembly for the treatment of at least one object.

The invention also relates to a method for the treatment of at least one object.

### BACKGROUND OF THE INVENTION

Plasma processes are currently used industrially in medical technology, the manufacture of materials, and lighting technology. In principle, the use of plasma permits a reduction of microbial contaminants at low temperatures, whereby the effect is primarily achieved on the surfaces. The first series of laboratory-scale experiments on plasma application in the food sector are mainly investigating possibilities for the inactivation of undesirable microorganisms in heat-sensitive foodstuffs, since conventional thermal decontamination processes are not applicable or only applicable to a limited extent to products such as fresh fruit and vegetables, meat, or eggs. Plasma application is also considered a potential alternative to other chemical (e.g., chlorine) or physical processes (e.g., high pressure, high voltage pulses, ionizing irradiation). Advantages of the plasma process are considered to include high efficiency at low temperatures (generally <70° C.), targeted and consumption-appropriate application, small effects on the inner product matrix, and water-free, solvent-free and residue-free, as well as resource-efficient application. Other processes such as high pressure and/or ionizing radiation are complex or costly. Decontamination with UV light is often ineffective and limited by shadow effects.

International patent application WO 1995/009256 A1 relates to the treatment, in particular the cleaning, of surfaces, in particular film and metal surfaces. Cleaning is achieved by a dielectrically impeded discharge acting on the surface of the film strip. Through the action of high-energy charged particles and photons from the UV spectral range, the oil or grease film, for example, after a short time, is removed to such an extent that further processing is possible.

European patent EP 1 337 281 B1 describes an enhancement of the cleaning effect of plasma. The enhancement of the indirect effect on the surface to be cleaned or sterilized is achieved by adding additive gas components such as oxygen, water vapor or noble gases.

German publication DE 100 36 550 A1 relates to a sterilization process in which the surface to be treated is exposed to a gas discharge. Sterilization is carried out in a gas atmosphere containing hydrogen and oxygen at a certain pressure. Optimum effectiveness is achieved in particular by humidified air (N₂+O₂+H₂O).

U.S. Patent Application No. 2015/0038584 A1 discloses a device for the plasma treatment of surfaces of objects. A spatial and temporal separation of the plasma process and the exposure of the object to be cleaned/sterilized is described.

U.S. Patent Application No. 2016/0220714 A1 discloses a disinfection device for plasma disinfection of surfaces with a plasma generator. To generate a disinfecting plasma gas stream, the plasma gas stream is in communication with the plasma generator. At least one partially closed disinfection area is provided which is configured to receive the surface to be disinfected. The disinfection device has an aerosol generator to generate an aerosol stream containing aqueous particles. The aerosol generator communicates with the plasma generator to direct the plasma gas stream mixed with the aerosol stream to the surface to be disinfected in the disinfection area.

Depending on the sterilization process, additional additives such as peracetic acid or hydrogen peroxide can be added to this activated water.

U.S. Patent Application No. 2003/0133832 A1 discloses the use of free hydroxyl radicals for sterilization or decontamination. The hydroxyl radicals have a particularly high oxidation potential. The hydroxyl radicals are formed by the photolytic reaction of ozone with water under UV light.

German patent application DE 10 2008 037 898 A1 relates to a process and a device for the disinfection or sterilization of packaging material and/or containers and/or filter material, wherein the material or container is treated with a gas produced in a plasma reactor.

German patent application DE 10 2015 119 369 A1 relates to a device as well as a system and a process for treating an object, in particular one or more free-form bodies, with plasma. The device serves to treat an object with plasma and comprises a wrapping device with which a substantially gas-tight receiving space is formed or can be formed in which an object to be treated can be received. Furthermore, the device comprises a first electrode and a second electrode, the two electrodes being arranged with respect to the wrapping device in such a way that, when an electrical potential difference is applied to the electrodes, a plasma can be generated in the receiving space of the wrapping device.

U.S. Patent Application No. 2017/112157 A1 discloses a process for treating a surface with a reactive gas. The reactive gas is produced from cold plasma at high voltage from a process gas (HVCP).

German patent application DE 10 2014 213 799 A1 discloses a domestic refrigerating appliance with a food treatment unit and a method for operating such a domestic refrigerating appliance. The domestic refrigerating appliance is provided with an interior space for storing food which is delimited by walls of an interior container. A food processing unit is also provided, the food processing unit being arranged in the domestic refrigerating appliance for acting on a surface of food introduced into the storage area, and being configured such that the acting is decontamination of pesticides and/or heavy metals in the food.

German patent application DE 10 2005 061 247 A1 discloses a method and a device for disinfecting food. The food is exposed to at least one atmospheric plasma jet. The energy contained in the plasma jet is used to disinfect the surface of the food.

German patent application DE 11 2015 006 315 T5 discloses a charge particle beam device with a sample chamber and a charge particle gun chamber. The sample chamber is brought into a high vacuum state and is evacuated via a main inlet with a turbo-molecular pump. This should make it possible to minimize the contamination of the interior of the device both in the high vacuum and in the rough vacuum state, whereby it is possible that a contamination of the sample under consideration is prevented.

U.S. Patent Application No. 2004/0084148 A1 discloses a device operating with low-pressure plasma. A substrate in the form of a film is introduced into the chamber from the outside. While reaction gas is introduced, the chamber is evacuated. The plasma can be generated by means of a high frequency.

German translation DE 60 2005 003 223 T2 of European patent EP 1 729 894 B2 discloses the deposition of a polymer on a substrate. The monomer is introduced into a plasma deposition chamber. In the chamber, a glow discharge is ignited by applying a voltage in the form of a pulsed field. The polymer layer forms on the surface of the substrate.

German patent application DE 43 18 086 A1 discloses the production of a polymeric coating on the inner surface of a hollow plastic body by low-pressure plasma polymerization. A plasma is generated by microwaves, and, under the respective plasma conditions, forms a polymerizable, essentially non-polar gaseous and/or vaporous starter substance. The layer-forming gas atmosphere may contain two or more components that on the one hand tend to chain growth and on the other hand tend to form branching or cross-linking sites.

U.S. Patent Application No. 2004/0129212 A1 discloses a device with which a chemically reactive precursor can be delivered to a surface to be treated. Specially designed outlets are provided to allow the precursor to deposit evenly on the surface.

U.S. Pat. No. 6,083,363 B1 discloses a device with which an even and uniform plasma treatment of a surface is possible. The treatment of the surface should be gentle; thereunto a means is provided between the plasma chamber and the reaction chamber with which ions can be extracted.

US patent application US 2012/0270406 A1 discloses a method for cleaning a plasma treatment apparatus.

All non-thermal processes (chemical, plasma chemical, physical or optical) are more effective the higher the concentration of the active species is and the higher the exposure time of the contaminated surface. In microbiological organisms, threshold values are often observed below which the effect disappears even after prolonged exposure. Thus complete decontamination cannot be achieved.

In direct treatment with chemical gas mixtures or liquids, such as ethylene oxide or H₂O₂, the concentration can be freely adapted to the process over a wide range. However, here it may be the case that concentrations that may be hazardous to health must be handled safely.

In UV or discharge processes, the concentration of the generated species depends strongly on the power and power density, which cannot be increased arbitrarily.

### SUMMARY OF THE INVENTION

It is an object of the invention to provide an assembly for the treatment of at least one object by means of which all surface areas of the object can be exposed during treatment. The above object is achieved by an assembly for treating at least one object, comprising: an ionization chamber/plasma chamber, connected to a high-voltage source via a high-voltage line; a first valve group having a plurality of valves; a second valve group comprising a plurality of valves, wherein a pump being provided between a node of the first valve group and a node of the second valve group; a treatment chamber, wherein the treatment chamber in fluidic connection with the first valve group via a valve of the first valve group and via a valve of the second valve group, and the ionization chamber/plasma chamber in fluidic connection to the first valve group via a valve of the first valve group and via a valve of the second valve group; at least one gas inlet connected to the first valve group via at least one valve of the first valve group, and a gas outlet connected to the second valve group via at least one valve.

A further object of the invention is to provide a method for treating at least one object, whereby during the treatment of the object all surface areas of the object are exposed to treatment.

This object is achieved by a method for treating at least one object, comprising the following steps: placing the at least one object into a treatment chamber; generating a negative pressure in the treatment chamber with a pump which is provided between a node of a first valve group with a plurality of valves and a node of a second valve group with a plurality of valves; filling an ionization chamber/plasma chamber with a process gas via a gas inlet which is connected to a valve of the first valve group and a valve of the second valve group; activating a discharge structure in the ionization chamber/plasma chamber so that the process gas is ionized or activated; extracting the activated or ionized process gas from the ionization chamber/plasma chamber into the treatment chamber by the negative pressure in the treatment chamber via a valve of the first valve group and a valve of the second valve group; pumping off and subsequently ventilating the treatment chamber after an exposure time of the object to the activated or ionized process gas; and, removing the at least one treated object from the treatment chamber.

A possible embodiment of the assembly for treatment of at least one object comprises an ionization chamber/plasma chamber connected to a high-voltage source via a high-voltage line. A discharge structure is provided in the ionization chamber/plasma chamber to which the high voltage is applied. By means of the discharge structure, the process gas in the ionization chamber/plasma chamber can be ionized, or a plasma can be generated with the process gas. The configuration of the discharge structure is well known in the state of the art, and here there is no need of a detailed description thereof. Of course, instead of a conventionally configured discharge structure also a direct piezoelectric discharge can be used, which also is described in a sufficient manner in the state of the art.

Furthermore, the assembly comprises a first valve group with several valves and a second valve group with several valves, whereby the first valve group and the second valve group each define a node. A pump is provided between the node of the first valve group and the node of the second valve group. The pump can be used to support gas transport within the assembly or to generate a negative pressure at elements of the assembly. A treatment chamber is in fluidic connection by a valve of the first valve group and a valve of the second valve group. The ionization chamber/plasma chamber is also in fluidic connection via a valve of the first valve group and a valve of the second valve group. The first and second valve groups can be used, for example, to supply gas to or discharge gas from the ionization chamber/plasma chamber or the treatment chamber in a targeted and controlled manner. The treatment chamber is equipped with an airlock for introducing an object into the treatment chamber.

The advantage of the assembly according to the invention is that a negative pressure prevails in the treatment chamber, which can then be actively filled with the activated process gas by means of the negative pressure. Thus it is possible that the space in the treatment chamber is completely filled and thus all gaps or depressions in the object can be reached. In addition, the assembly represents a closed system. Another advantage is the free selection of the process pressure in the ionization chamber/plasma chamber during ionization, which is favored when the pressure is lowered. Of course, the object can also be moved during treatment with the activated process gas to facilitate contact with all surfaces of the object.

Another advantage of the assembly according to the invention is that the partial pressures and thus the absolute quantities of certain material components, which are added for the treatment of the objects, can be precisely determined and dosed during the process.

A gas inlet through which process gas is provided is connected via a valve of the first valve group. A gas outlet through which, for example, excess process gas or gas is discharged from the treatment chamber is connected to the second valve group via a valve. The advantage of the gas inlet is that a gas mixture such as moist air can be produced here. In addition, the inlet gas (process gas) can be filtered. A residue filter or dirt filter can be integrated in the gas outlet.

The first valve group comprises several valves. The second valve group also includes several valves. The valves of the first and second valve groups can be controlled, e.g., by a controller, as and when required to regulate the gas flow between the ionization chamber/plasma chamber, treatment chamber, gas inlet and/or gas outlet as and when required. The control can be realized e.g., from a computer, tablet or mobile phone. The valves are equipped with actuators so that the required valve position can be set. The controller can also be communicatively connected to the high-voltage source, the discharge structure, the ionization chamber/plasma chamber or the treatment chamber. The communicative connection can be wired or wireless.

The treatment chamber is in fluidic connection via a line to a valve of the first valve group and is in fluidic connection via a line to a valve of the second valve group.

The ionization chamber/plasma chamber is in fluidic connection via a line to a valve of the first valve group and is in fluidic connection via a line to a valve of the second valve group.

The gas inlet is in fluidic connection via a line to a valve of the first valve group. The gas outlet is in fluidic connection via a line to a valve of the second valve group.

The inventive method for treating at least one object is characterized by the fact that first at least one object is brought into a treatment chamber. The treatment chamber can have an airlock for this purpose. After the object has been brought into the treatment chamber, a negative pressure can be generated in the treatment chamber with a pump. An ionization chamber/plasma chamber is filled with a process gas via a gas inlet. The process gas is activated in the ionization chamber/plasma chamber with a discharge structure so that the process gas is ionized or activated. The activated or ionized process gas is extracted from the ionization chamber/plasma chamber into the treatment chamber. The activated process gas is extracted by means of the negative pressure prevailing in the treatment chamber. After an exposure time of the object to the activated or ionized process gas, the process gas is pumped out of the treatment chamber. The treatment chamber then is ventilated and the at least one treated object is removed from the treatment chamber.

The pump is provided between a node of the first valve group and a node of the second valve group. The pump can at least optionally apply a negative pressure to the treatment chamber. After an exposure time of the at least one object, the activated or ionized process gas can also be pumped out of the treatment chamber.

By means of the pump, an enrichment cycle (sustained supply of process gas into the ionization chamber/plasma chamber) of activated or ionized process gas can be carried out in the ionization chamber/plasma chamber. During the enrichment cycle, the discharge structure in the ionization chamber/plasma chamber is activated. A valve of the first valve group and a valve of the second valve group are open so that the ionization chamber/plasma chamber is connected to the pump via a fluid circuit.

The at least one object is introduced into the treatment chamber via an airlock. Therein a valve of the first valve group and a valve of the second valve group are open so that the treatment chamber forms a fluid connection with the gas outlet via the second valve group.

The pump is activated to create the negative pressure in the treatment chamber. Therein a valve of the first valve group and a valve of the second valve group are open so that the treatment chamber forms a fluidic connection to the gas outlet.

For filling the ionization chamber/plasma chamber with the process gas, a valve of the first valve group and a valve of the second valve group are open. In this way a gas inlet is connected to the ionization chamber/plasma chamber by means of a fluid connection. At the activated discharge structure in the ionization chamber/plasma chamber the process gas is ionized or activated. Therein a valve of the first valve group and a valve of the second valve group are open. Thus there is a fluid connection from the treatment chamber via the pump to the gas outlet.

In a next step, the activated or ionized process gas is extracted from the ionization chamber/plasma chamber into the treatment chamber. The extraction can occur because of a negative pressure in the treatment chamber. Therein a valve and a further valve of the first valve group are open so that there is a fluid connection from the ionization chamber/plasma chamber to the treatment chamber. The valve and the further valve of the first valve group remain open during an exposure time of the object to the ionized or activated process gas in the treatment chamber.

For pumping out the treatment chamber, a valve of the first valve group and a valve of the second valve group are open. In this way there is a fluidic connection from the treatment chamber via the pump to a gas outlet.

For ventilating the treatment chamber, a valve and a further valve of the second valve group are open. In this way there is a fluidic connection from the treatment chamber to a gas outlet.

If a suitable process is selected, it is possible to run all processes at negative pressure in relation to the environment or at positive pressure in relation to the environment.

A controller can be communicatively connected with the assembly. With the controller, at least the discharge structure of the ionization chamber/plasma chamber, the valves of the first valve group and the valves of the second valve group can be controlled in time and as required.

### BRIEF DESCRIPTION OF THE DRAWINGS

The embodiments are best understood with reference to the accompanying figures. The size proportions in the figures do not always correspond to the actual size proportions, since some shapes are shown simplified and other shapes are shown enlarged in relation to other elements for better illustration.

FIG. 1 is a schematic representation of a possible embodiment of the assembly according to the invention for the treatment of at least one object;

FIG. 2 is a schematic representation of the assignment of a controller to the assembly according to the invention;

FIG. 3 is a flow chart of the method according to the invention for the treatment of at least one object;

FIG. 4 illustrates a circuit with the ionization chamber/plasma chamber;

FIG. 5 illustrates the fluid connection of the treatment chamber to the gas outlet;

FIG. 6 illustrates the fluid connection for generating the negative pressure in the treatment chamber;

FIG. 7 illustrates the fluid connection of the gas inlet with the ionization chamber/plasma chamber;

FIG. 8 illustrates the fluidic connection of the treatment chamber to the gas outlet;

FIG. 9 illustrates the fluidic connection from the ionization chamber/plasma chamber to the treatment chamber;

FIG. 10 illustrates the fluidic connection for pumping the process gas out of the treatment chamber; and,

FIG. 11 illustrates the fluidic connection for ventilating the treatment chamber.

### DETAILED DESCRIPTION OF THE DRAWINGS

Identical reference signs are used for identical elements of the invention or elements of like function. Furthermore, for the sake of clarity, only the reference signs required for the description of the respective figures are shown in the individual figures. The following discussion of the figures describes the assembly and method with a first group of valves comprising three valves and a second group of valves also comprising three valves. This is for descriptive purposes only and should not be construed as a limitation of the invention.

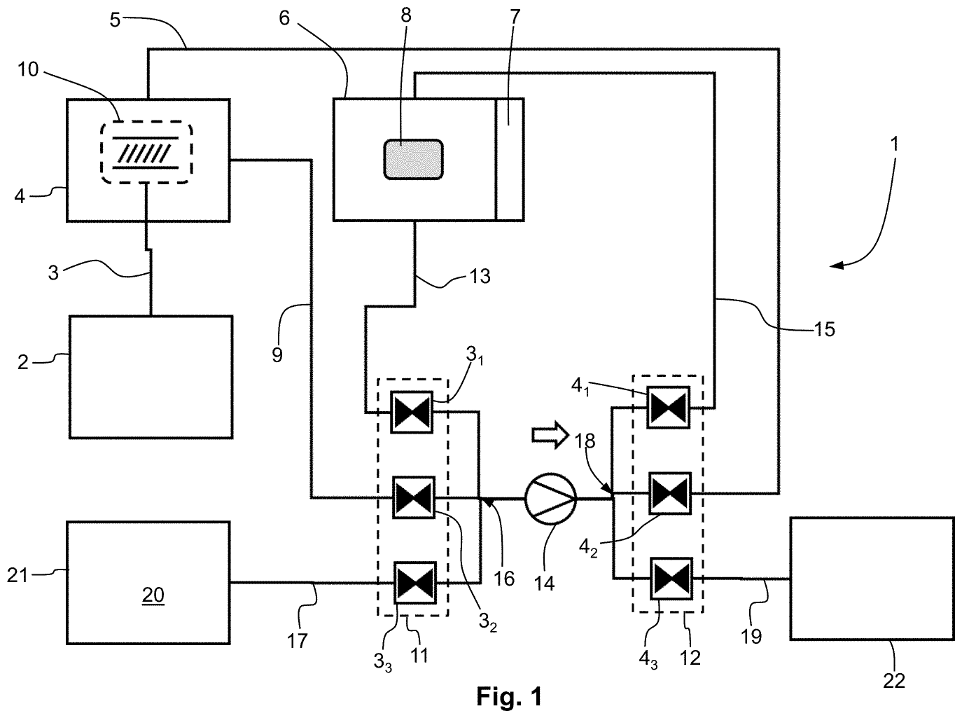

FIG. 1 shows a schematic representation of a possible embodiment of the assembly 1 according to the invention for the treatment of at least one object 8. The assembly 1 has an ionization chamber/plasma chamber 4 in which a discharge structure 10 is provided. A high-voltage source 2 is connected to the discharge structure 10 in the ionization chamber/plasma chamber 4 via a high-voltage line 3. Assembly 1 also includes a treatment chamber 6 provided with an airlock 7. Via airlock 7 at least one object 8 can be brought into treatment chamber 6. A first valve group 11 and a second valve group 12 are assigned to assembly 1. The first valve group 11 has a node 16 and the second valve group 12 a node 18. The first node 16 and the second node 18 are defined by the meeting of the lines from the valves 3₁, 3₂, and 3₃ of the first valve group 11 and by the meeting of the lines from the valves 4₁, 4₂, and 4₃ of the second valve group 12. A pump 14 connects the first valve group 11 with the second valve group 12 via nodes 16 and 18.

In assembly 1 the treatment chamber 6 is in fluidic connection to the first valve group 11 and to the second valve group 12. The ionization chamber/plasma chamber 4 is also in fluidic connection to the first valve group 11 and the second valve group 12. In addition, a gas inlet 21 is connected to the first valve group 11 and a gas outlet 22 to the second valve group 12.

The treatment chamber 6 is in fluidic connection by a line 13 to the first valve 3₁ of the first valve group 11 and is in fluidic connection by a line 15 to the first valve 4₁ of the second valve group 12. The ionization chamber/plasma chamber 4 is in fluidic connection via a line 9 to the second valve 3₂ of the first valve group 11 and is in fluidic connection via a line 5 to the second valve 4₂ of the second valve group 12. Gas inlet 21 is in fluidic connection to the third valve 3₃ of the first valve group 11 via a line 17. The gas outlet 22 is in fluidic connection to the third valve 4₃ of the second valve group 12 via a line 19.

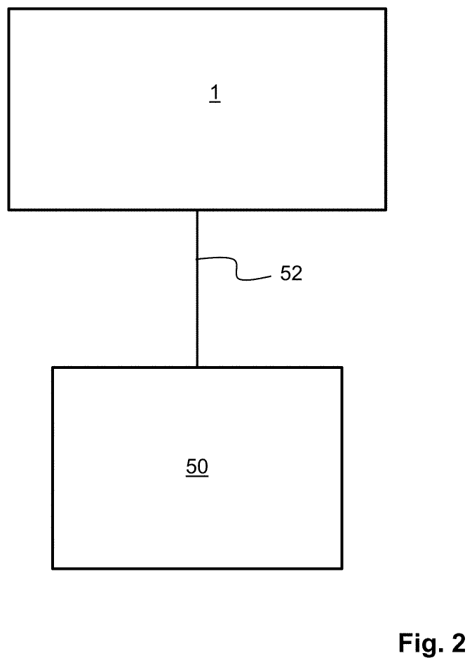

FIG. 2 shows a schematic representation of the assignment of a controller 50 to the assembly 1 according to the invention. The controller 50 is connected to assembly 1 via a communication link 52. With the controller 50, at least the valves 3₁, 3₂, and 3₃ of the first valve group 11, the valves 4₁, 4₂, and 4₃ of the second valve group 12, the high-voltage source 2, the discharge structure 10, and the pump 14 can be controlled and regulated as required and in time. Communication link 52 can be wired or wireless.

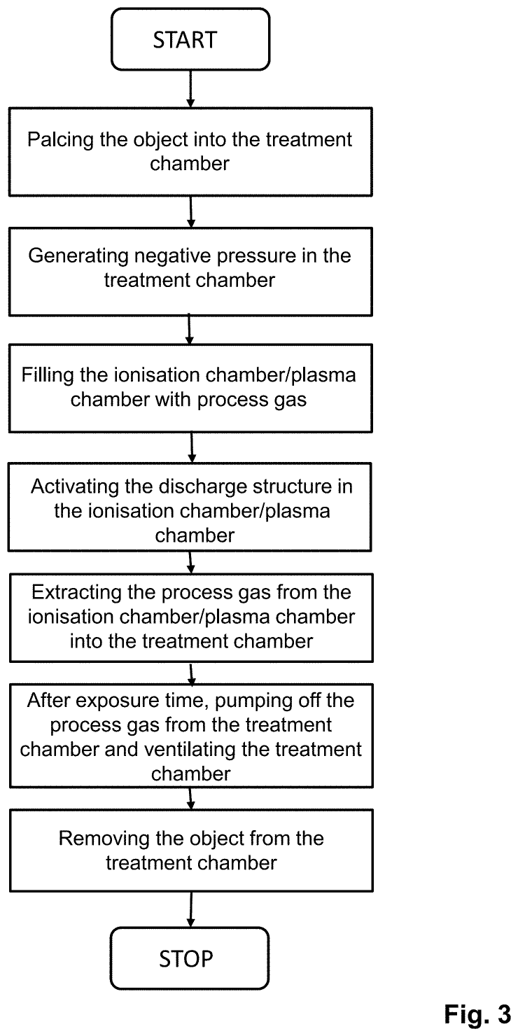

FIG. 3 shows a flowchart of the method according to the invention for the treatment of at least one object 8. First, the at least one object 8 is brought into a treatment chamber 6 of assembly 1 for treatment. This is done via an airlock 7. Once the at least one object 8 is located in the treatment chamber 6 and the airlock 7 has been closed, a pump 14 is activated. The pump 14 generates a negative pressure in the treatment chamber 6. For generating the negative pressure, the first valve 3₁ of the first valve group 11 and the third valve 4₃ of the second valve group 12 are opened so that the treatment chamber 6 forms a fluidic connection 103 to the gas outlet 22. The remaining valves 3₂ and 3₃ of the first valve group 11 and the valves 4₁ and 4₂ of the second valve group 12 remain closed.

Then the ionization chamber/plasma chamber 4 is filled with a process gas 20 via the gas inlet 21. Therein a third valve 3₃ of the first valve group 11 and a second valve 4₂ of the second valve group 12 are open. The gas inlet 21 thus is in fluidic connection to the ionization chamber/plasma chamber 4 via the first valve group 11 and the second valve group 12. The discharge structure 10 in the ionization chamber/plasma chamber 4 is activated by the high-voltage source 2 so that ionization or activation of the process gas 20 occurs. Here the remaining valves 3₁ and 3₂ of the first valve group 11 and the valves 4₁ and 4₃ of the second valve group 12 are closed.

The activated or ionized process gas 20 is extracted by means of negative pressure from the ionization chamber/plasma chamber 4 into the treatment chamber 6. The negative pressure in the treatment chamber 6 ensures that the activated or ionized process gas 20 passes from the ionization chamber/plasma chamber 4 into the treatment chamber 6. Therein the first valve 3₁ and the second valve 3₂ of the first valve group 11 are open, thus the ionization chamber/plasma chamber 4 and the treatment chamber 6 are in fluidic connection to each other.

The first valve 3₁ and the second valve 3₂ remain open during an exposure time. The valve 3₃ of the first valve group 11 and the valves 4₁, 4₂, and 4₃ of the second valve group 12 remain closed.

After the exposure time of the object 8 to the activated or ionized process gas 20, the process gas 20 is pumped out of treatment chamber 6. The treatment chamber 6 then is ventilated. Finally, the at least one treated object 8 is removed from the treatment chamber 6 via the airlock 7.

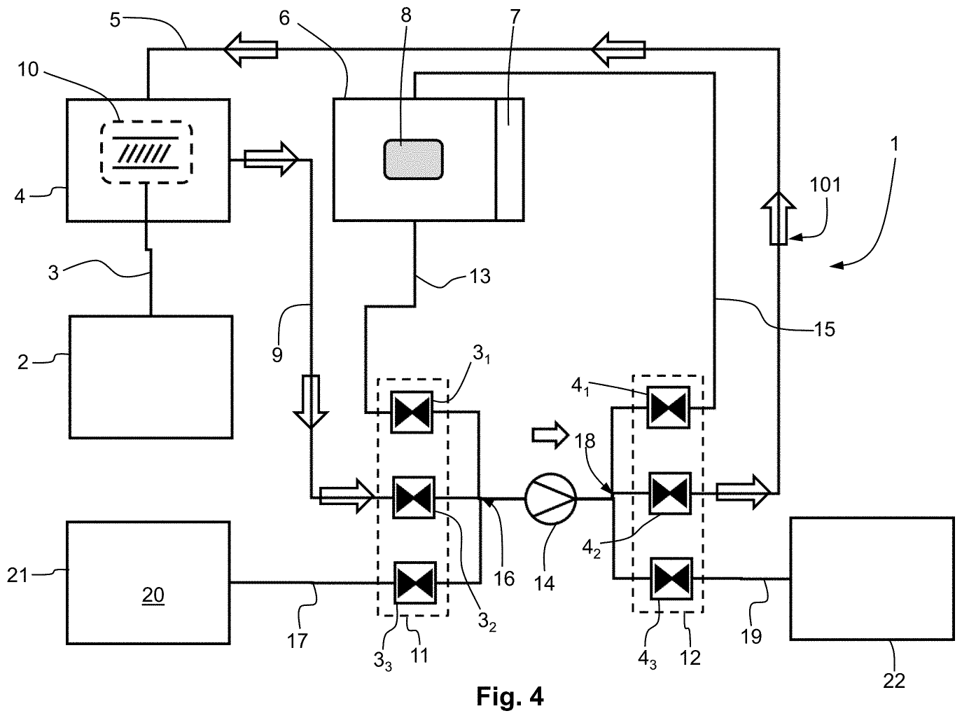

FIG. 4 shows a representation of the formation of a circuit 101 in assembly 1, where the ionization chamber/plasma chamber 4 is integrated into the circuit 101. Pump 14 is used to perform an enrichment cycle of activated or ionized process gas 20 in the ionization chamber/plasma chamber 4. For the enrichment cycle, the second valve 3₂ of the first valve group 11 and the second valve 4₂ of the second valve group 12 are open. This defines the circuit 101 so that the ionization chamber/plasma chamber 4 and the pump 14 are in fluidic connection to each other.

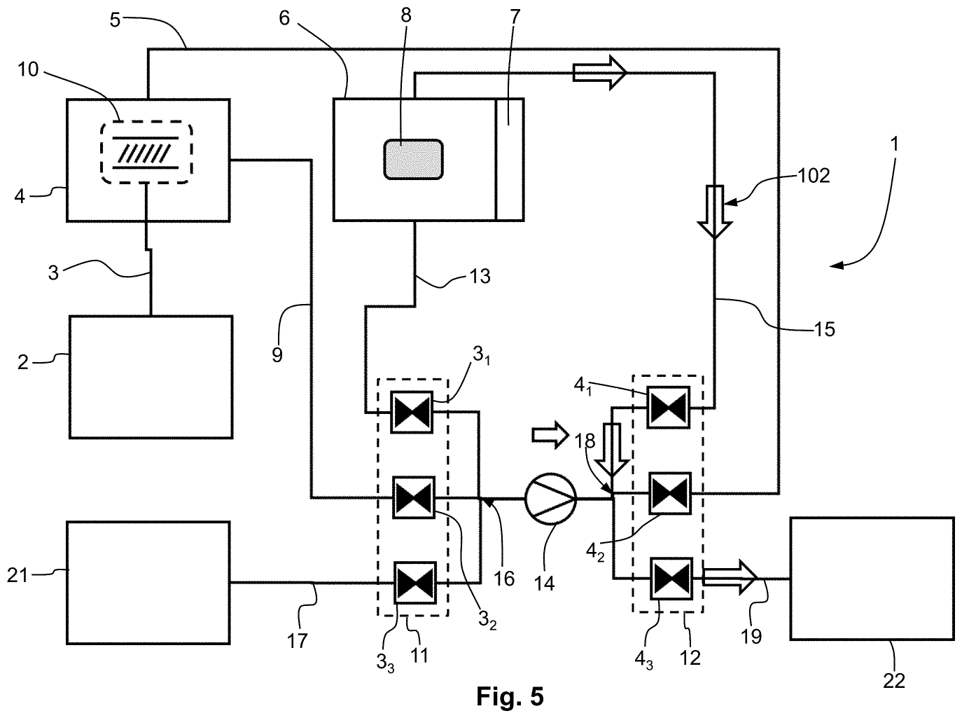

FIG. 5 shows a fluidic connection 102 between the treatment chamber 6 and the gas outlet 22. To realize the fluidic connection 102, the first valve 4₃ and the third valve 4₃ of the second valve group 12 are open, so that the treatment chamber 6 forms the fluidic connection 102 via the second valve group 12 with the gas outlet 22.

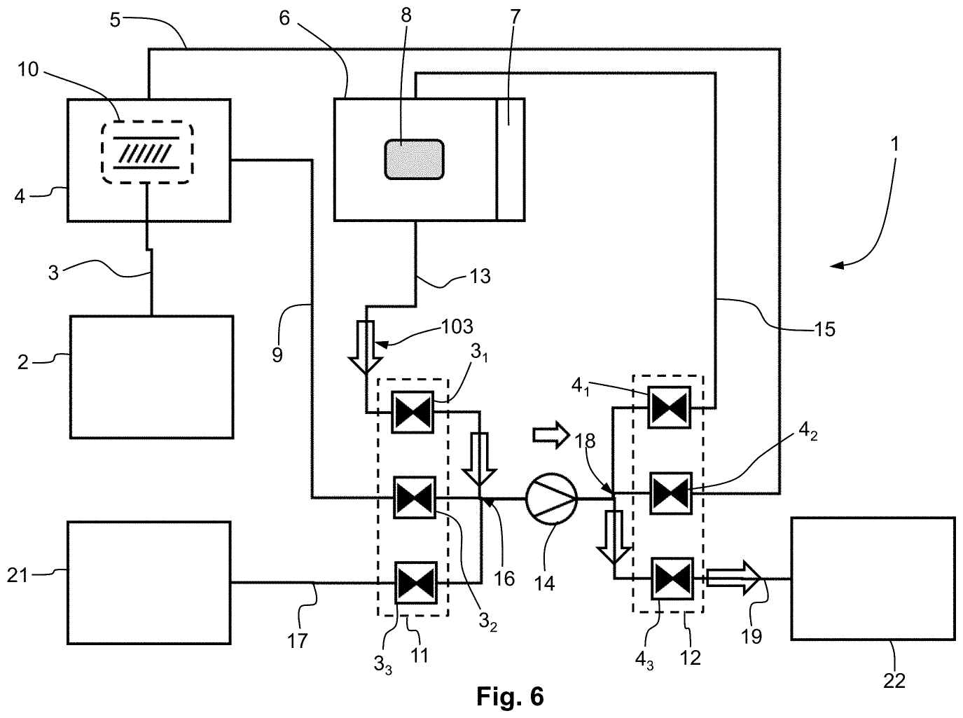

FIG. 6 shows a representation of the fluidic connection 103 for generating the negative pressure in the treatment chamber 6. The fluidic connection 103 runs from the treatment chamber 6 via the first valve 3₁ of the first valve group 11, the pump 14 and the third valve 4₃ of the second valve group 12 to the gas outlet 22. The negative pressure in the treatment chamber 6 is generated by means of the pump 14. Therein the first valve 3₁ of the first valve group 11 and the third valve 4₃ of the second valve group 12 are open.

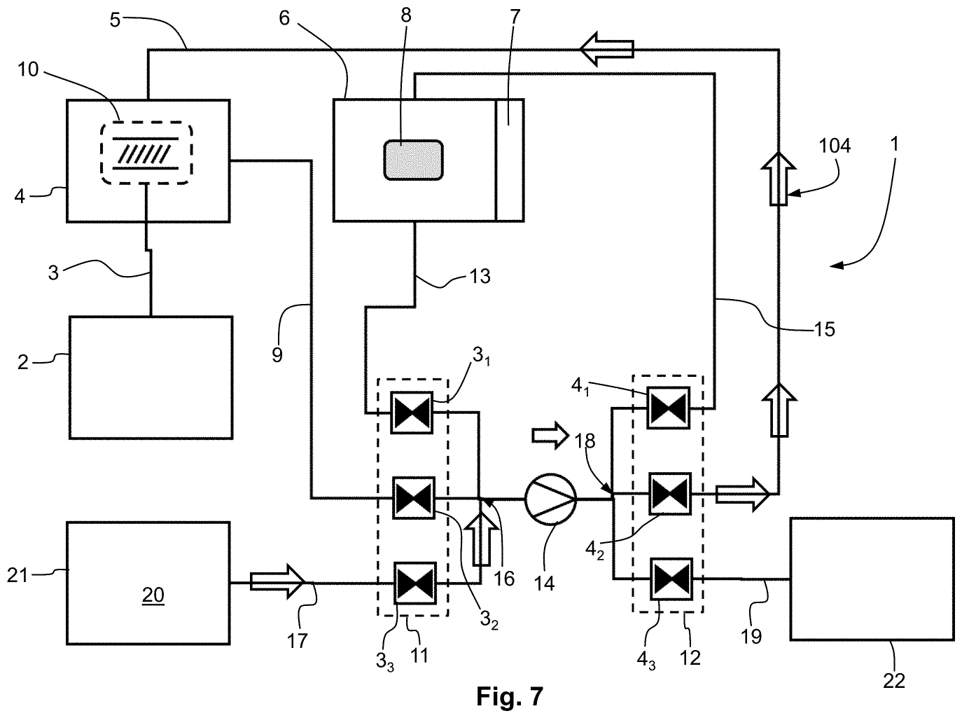

FIG. 7 shows the fluidic connection 104 of the gas inlet 21 with the ionization chamber/plasma chamber 4. The fluidic connection 104 runs from the gas inlet 21 via the third valve 3₃ of the first valve group 11 and the second valve 4₂ of the second valve group 12 to the ionization chamber/plasma chamber 4. Via the fluidic connection 104 the ionization chamber/plasma chamber 4 can be filled with the process gas 20. The third valve 3₃ of the first valve group 11 and the second valve 4₂ of the second valve group 12 are open.

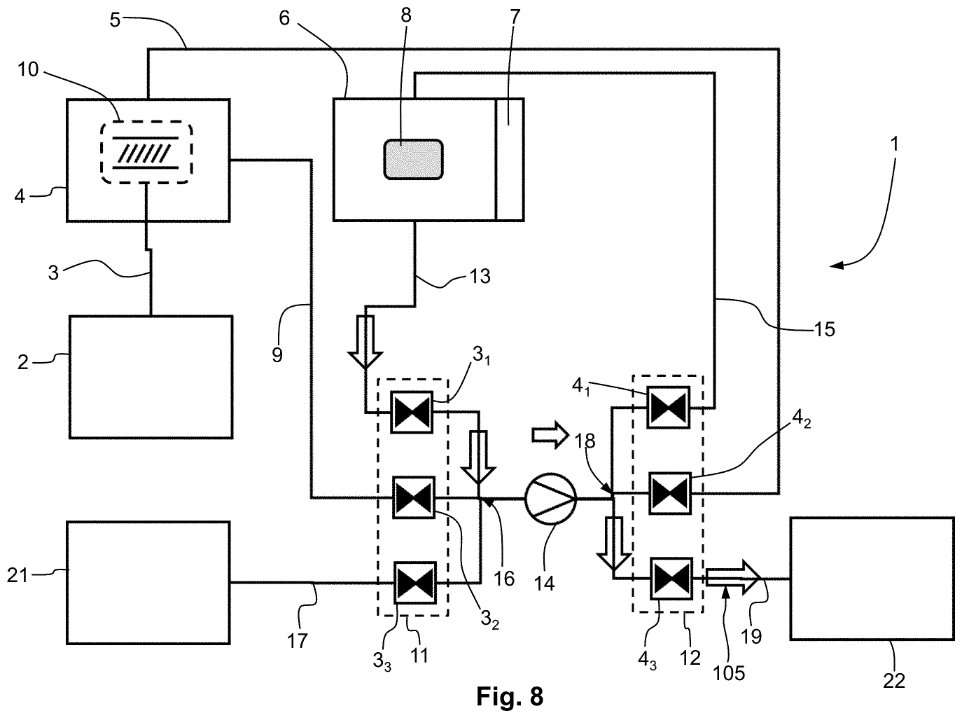

FIG. 8 is a representation of the fluidic connection 105 of the treatment chamber 6 to the gas outlet 22 of the treatment chamber 6. At the activated discharge structure 10 in the ionization chamber/plasma chamber 4 the process gas 20 is ionized or activated. The fluidic connection 105 runs from the treatment chamber 6 via a line 13 to the first valve 3₁ of the first valve group 11, the pump 14, and the third valve 4₃ of the second valve group 12 to the gas outlet 22. Therein the first valve 3₁ of the first valve group 11 and the third valve 4₃ of the second valve group 12 are open.

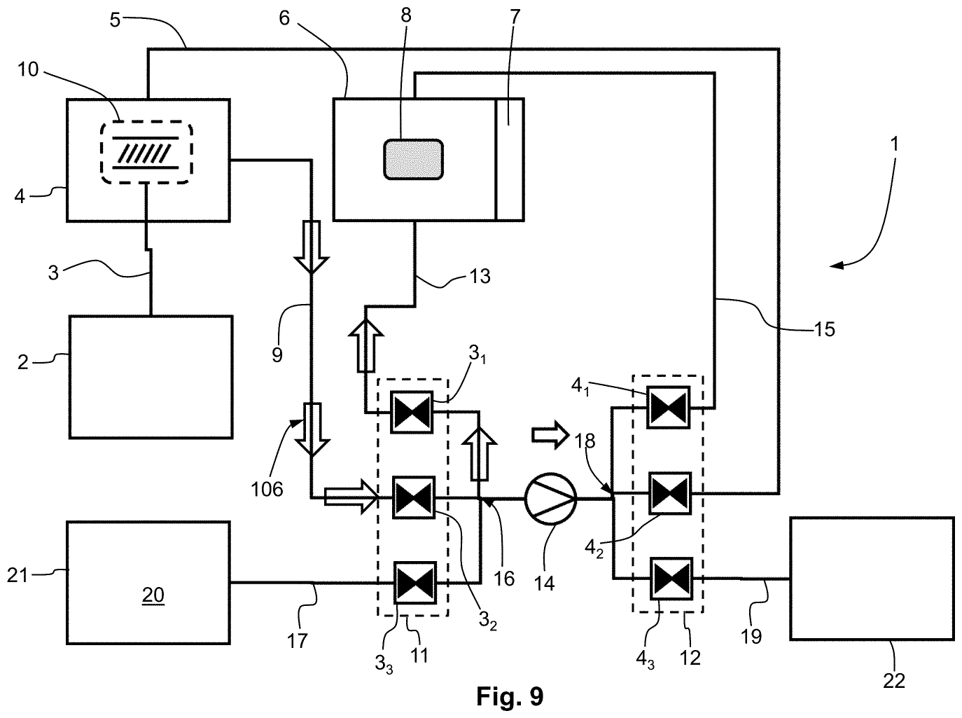

FIG. 9 shows the fluidic connection 106 from the ionization chamber/plasma chamber 4 to the treatment chamber 6. The activated or ionized process gas 20 is extracted from the ionization chamber/plasma chamber 4 into the treatment chamber 6. Therein the fluidic connection 106 runs from the ionization chamber/plasma chamber 4 via the second valve 3₂ and the first valve 3₁ of the first valve group 11 to the treatment chamber 6. Therein the first valve 3₁ and the second valve 3₂ of the first valve group 11 are open. The first valve 3₁ and the second valve 3₂ remain open during an exposure time of the object in the treatment chamber 6 to the activated or ionized process gas 20.

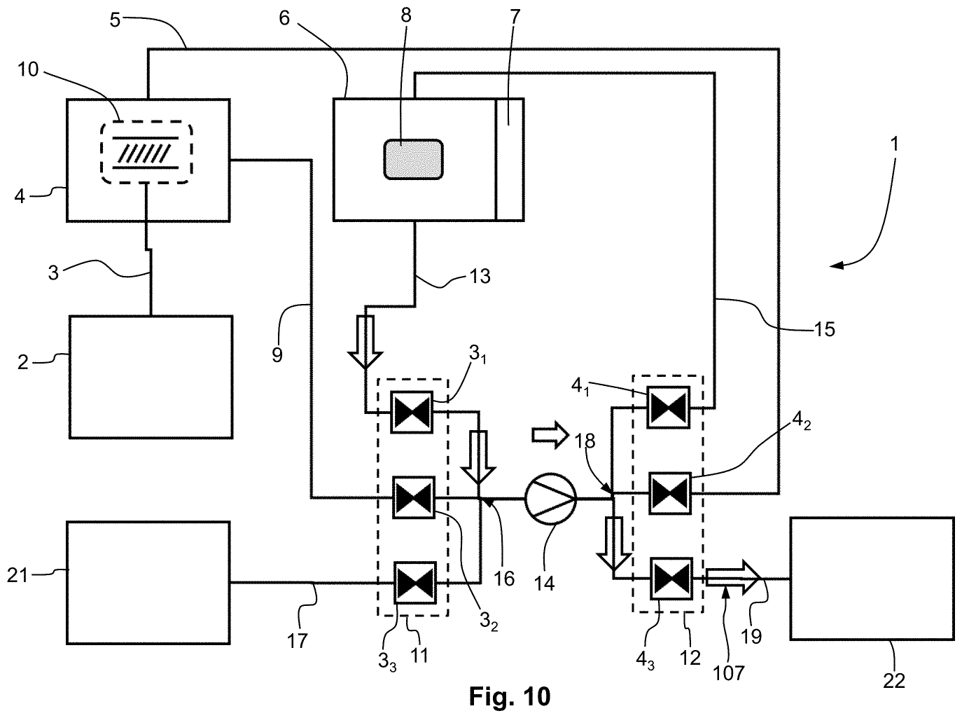

FIG. 10 shows the fluidic connection 107 for pumping the process gas 20 out of the treatment chamber 6. The fluidic connection 107 for pumping off the treatment chamber 6 runs from the treatment chamber 6 via the first valve 3₁ of the first valve group 11, the pump 14 and the third valve 4₃ of the second valve group 12 to the gas outlet 22. The first valve 3₁ of the first valve group 11 and the third valve 4₃ of the second valve group 12 are open.

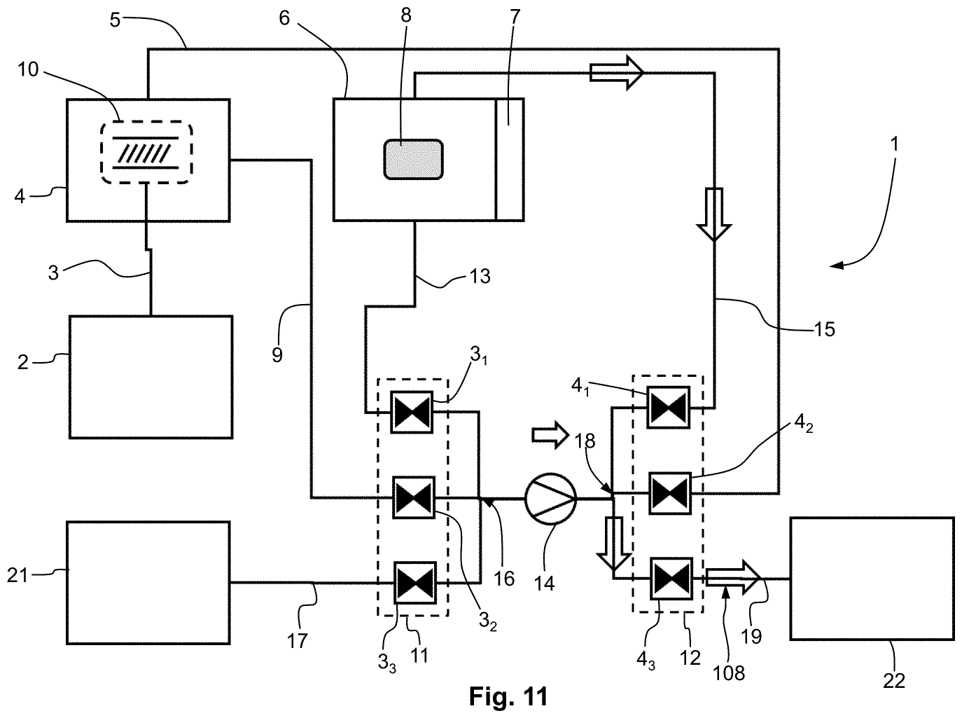

FIG. 11 shows the fluidic connection 108 for ventilating the treatment chamber 6. The fluidic connection 108 for ventilation runs from treatment chamber 6 via the first valve 4₁ and the third valve 4₃ of the second valve group 12 to the gas outlet 22. The first valve 4₁ and the third valve 4₃ of the second valve group 12 are open.

The invention has been described with reference to preferred embodiments. However, it would have been obvious to a person skilled in the art that changes and modifications can be made without leaving the scope of protection of the appended claims.

### REFERENCE SIGNS

1 Assembly
2 High-voltage source
3 High-voltage line
3₁, 3₂, . . . , 3_{N} Valve
4 Ionization chamber/Plasma chamber
4₁, 4₂, . . . , 4_{N} Valve
5 Line
6 Treatment chamber
7 Airlock
8 Object
9 Line
10 Discharge structure
11 First valve group
12 Second valve group
13 Line
14 Pump
15 Line
16 Node
17 Line
18 Node
19 Line
20 Process gas
21 Gas inlet
22 Gas outlet
50 Controller
52 Communication link
101 Circuit
102 Fluidic connection
103 Fluidic connection
104 Fluidic connection
105 Fluidic connection
106 Fluidic connection
107 Fluidic connection
108 Fluidic connection

What is claimed is:

1. An assembly for treating at least one object, comprising:
an ionization chamber/plasma chamber, connected to a high-voltage source via a high-voltage line;
a first valve group having a plurality of valves;
a second valve group comprising a plurality of valves, wherein a pump being provided between a node of the first valve group and a node of the second valve group;
a treatment chamber, wherein the treatment chamber in fluidic connection with the first valve group via a valve of the first valve group and via a valve of the second valve group, and the ionization chamber/plasma chamber in fluidic connection to the first valve group via a valve of the first valve group and via a valve of the second valve group;
at least one gas inlet connected to the first valve group via at least one valve of the first valve group, and a gas outlet connected to the second valve group via at least one valve.

2. The assembly of claim 1, wherein the treatment chamber is in fluidic connection via a line to one of the valves of the first valve group and is in fluidic connection via a line to one of the valves of the second valve group.

3. The assembly of claim 1, wherein the ionization chamber/plasma chamber is in fluidic connection via a line to one of the valves of the first valve group, and is in fluidic connection via a line to one of the valves of the second valve group.

4. The assembly of claim 1, wherein the at least one gas inlet is in fluidic connection via a line to one of the valves of the first valve group, and the gas outlet is in fluidic connection via a line to one of the valves of the second valve group.

5. The assembly of claim 1, wherein a controller is connected to the assembly via a communication link, and, by means of the controller, at least the valves of the first valve group, the valves of the second valve group, the high-voltage source, a discharge structure and the pump are controlled according to need and in time.

6. A method for treating at least one object, characterized by the following steps:
placing the at least one object into a treatment chamber;
generating a negative pressure in the treatment chamber with a pump which is provided between a node of a first valve group with a plurality of valves and a node of a second valve group with a plurality of valves;
filling an ionization chamber/plasma chamber with a process gas via a gas inlet which is connected to a valve of the first valve group and a valve of the second valve group;
activating a discharge structure in the ionization chamber/plasma chamber so that the process gas is ionized or activated;
extracting the activated or ionized process gas from the ionization chamber/plasma chamber into the treatment chamber by the negative pressure in the treatment chamber via a valve of the first valve group and a valve of the second valve group;
pumping off and subsequently ventilating the treatment chamber after an exposure time of the object to the activated or ionized process gas; and,
removing the at least one treated object from the treatment chamber.

7. The method of claim 6, wherein, by means of the pump, an enrichment cycle of activated or ionized process gas in the ionization chamber/plasma chamber is carried out, wherein the discharge structure in the ionization chamber/plasma chamber is activated, and a valve of the first valve group and a valve of the second valve group are open so that the ionization chamber/plasma chamber is in fluidic connection to the pump by a circuit.

8. The method of claim 6, wherein the at least one object is placed in the treatment chamber via an airlock, wherein a valve of the second valve group and a further valve of the second valve group are open, so that the treatment chamber forms a fluidic connection via the second valve group with a gas outlet.

9. The method of claim 6, wherein the pump is activated for generating the negative pressure in the treatment chamber, and a valve of the first valve group and a valve of the second valve group are open, so that the treatment chamber forms a fluidic connection to a gas outlet.

10. The method of claim 6, wherein for filling the ionization chamber/plasma chamber with the process gas a valve of the first valve group and a valve of the second valve group are open so that a gas inlet forms a fluidic connection to the ionization chamber/plasma chamber.

11. The method of claim 6, wherein an ionization or activation of the process gas takes place in the ionization chamber/plasma chamber at the activated discharge structure, wherein a valve of the first valve group and a valve of the second valve group are open so that there is a fluidic connection from the treatment chamber via the pump to the gas outlet.

12. The method of claim 6, wherein the activated or ionized process gas is extracted from the ionization chamber/plasma chamber into the treatment chamber, a valve and a further valve of the first valve group being open, so that a fluidic connection exists from the ionization chamber/plasma chamber to the treatment chamber, and the valve and the further valve of the first valve group remain open during an exposure time.

13. The method of claim 6, wherein for pumping off the treatment chamber a valve of the first valve group and a valve of the second valve group are open so that there is a fluidic connection from the treatment chamber via the pump to a gas outlet.

14. The method of claim 6, wherein for ventilating the treatment chamber a valve and a further valve of the second valve group are open so that a fluidic connection is formed from the treatment chamber to a gas outlet.

15. The method of claim 6, wherein a controller is communicatively connected to the assembly so that at least the discharge structure of the ionization chamber/plasma chamber, the valves of the first valve group and the valves of the second valve group are controlled in time.
